(19) United States
(12) Patent Application Publication
(10) Pub. No.: US 2024/0088133 A1
(43) Pub. Date: Mar. 14, 2024

(54) TRANSISTOR DEVICES WITH INTEGRATED DIODES

(71) Applicant: INTEL CORPORATION, Santa Clara, CA (US)

(72) Inventors: Nicholas A. Thomson, Hillsboro, OR (US); Ayan Kar, Portland, OR (US); Kalyan C. Kolluru, Portland, OR (US); Mauro J. Kobrinksy, Portland, OR (US); Benjamin Orr, Beaverton, OR (US)

(21) Appl. No.: 17/943,840

(22) Filed: Sep. 13, 2022

(51) Int. Cl. H01L 27/02; H01L 23/528; H01L 29/06; H01L 29/861

(52) U.S. Cl. CPC H01L 27/0255; H01L 23/5283; H01L 27/0266; H01L 29/0673; H01L 29/8611

(57) ABSTRACT

An integrated circuit structure includes a sub-fin having a first type of dopant, a first diffusion region having the first type of dopant and in contact with the sub-fin, and a second diffusion region and a third diffusion region having a second type of dopant and in contact with the sub-fin. The first type of dopant is one of p-type or n-type dopant, and where the second type of dopant is the other of the p-type or n-type dopant. A first body of semiconductor material extends from the second diffusion region to the third diffusion region, and a second body of semiconductor material extends from the first diffusion region towards the second diffusion region. The first diffusion region is a tap diffusion region contacting the sub-fin. In an example, the first diffusion region facilitates formation of a diode for electrostatic discharge (ESD) protection of the integrated circuit structure.

### FIELD OF THE DISCLOSURE

The present disclosure relates to integrated circuits, and more particularly, to transistor devices.

### BACKGROUND

During an electrostatic discharge (ESD) event in an integrated circuit (IC), an input/output (I/O) pad may experience high voltage. Various ESD protection devices are used, e.g., to protect the IC from failure during the ESD event. For example, transistors and/or diodes may be used as an ESD protection device in high-speed I/O designs, where the high voltage is grounded through these devices. Designing ESD protection devices involves many non-trivial issues.

### BRIEF DESCRIPTION OF THE DRAWINGS

FIGS. 1A and 1B are cross-sectional views of an integrated diode-transistor circuit structure that includes (i) a sub-fin comprising p-type dopant, (ii) a first diffusion region comprising the p-type dopant in contact with the sub-fin, (iii) a second diffusion region comprising n-type dopant in contact with the sub-fin, (iv) a third diffusion region comprising the n-type dopant in contact with the sub-fin, and (v) one or more bodies (e.g., channel regions, such as nanoribbons, nanowires, or a fin) of semiconductor material laterally extending from the second diffusion region to the third diffusion region, wherein the second and third diffusion regions and the bodies are part of a transistor device, and wherein the first diffusion region facilitates formation of parasitic diodes usable to protect the transistor device against ESD events, in accordance with an embodiment of the present disclosure.

FIGS. 1C and 1D illustrate the structure of FIGS. 1A and 1B, and are used to further illustrate example functionalities of the structure of FIGS. 1A and 1B, in accordance with an embodiment of the present disclosure.

FIG. 2 is a cross-sectional view of the integrated diode-transistor circuit structure of FIGS. 1A-1D laterally adjacent to a transistor structure, in accordance with an embodiment of the present disclosure.

FIG. 3 is a cross-sectional view of another integrated diode-transistor circuit structure, in accordance with an embodiment of the present disclosure.

FIG. 4 illustrates a flowchart depicting a method of forming an integrated diode-transistor circuit structure laterally adjacent to a transistor structure, in accordance with an embodiment of the present disclosure.

FIGS. 5A, 5B, 5C, 5D, 5E, 5F, 5G, and 5H collectively illustrate cross-sectional views of the integrated diode-transistor circuit structure and the laterally adjacent transistor structure in various stages of processing in the methodology of FIG. 4, in accordance with an embodiment of the present disclosure.

FIG. 6 illustrates a computing system implemented with integrated circuit structures (such as the diode structures illustrated in FIGS. 1A-3B) formed using the techniques disclosed herein, in accordance with some embodiments of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

Integrated circuit structures including diodes that are integrated with transistors are provided herein, where a diode can be used to protect a corresponding transistor from ESD events. In one embodiment, an integrated circuit structure comprises (i) a sub-fin having a first type of dopant, (ii) a first diffusion region comprising the first type of dopant and in contact with the sub-fin, and (iii) a second diffusion region and a third diffusion region, each of the second and third diffusion regions comprising a second type of dopant and in contact with the sub-fin. The first type of dopant is one of a p-type or an n-type dopant, and the second type of dopant is the other of the p-type or the n-type dopant. In an example, the second diffusion region is laterally between the first and third diffusion regions. In an example, the second diffusion region is a drain region of a transistor, and the third diffusion region is a source region of the transistor. A first body of semiconductor material extends from the second diffusion region to the third diffusion region, and forms a channel region of the transistor. A second body of semiconductor material extends from the first diffusion region towards the second diffusion region. In an example, each of the first and second bodies is a nanoribbon, a nanowire, or a fin. In an example, the drain region is coupled to an I/O terminal of an integrated circuit chip that includes the diffusion regions. In an example, the I/O terminal may experience ESD events. The first diffusion region is a tap diffusion region contacting the sub-fin. In an example, the first diffusion region facilitates formation of a diode for ESD protection of the transistor, e.g., where the diode is formed based on a PN junction between the sub-fin and the drain region.

In another embodiment, an integrated circuit structure comprises a sub-fin having a first type of dopant, a diffusion region having the first type of dopant and in contact with the sub-fin, and a source region and a drain region comprising a second type of dopant and in contact with the sub-fin. A first plurality of interconnect features electrically couple the diffusion region and the source region to a first terminal, and a second plurality of interconnect features electrically couple the drain region to a second terminal. In an example, one of the first or second terminals is an input/output (I/O) terminal of the integrated circuit structure. For example, the second terminal is the I/O terminal. In an example, the first terminal is a power or a ground terminal, e.g., depending on a type of a transistor (e.g., PMOS or NMOS) comprising the source and drain regions.

In yet another embodiment, an integrated circuit structure comprises a sub-fin having a first type of dopant, and a source region and a drain region comprising a second type of dopant. In an example, the source and drain regions are in contact with, and extend vertically upward from, the sub-fin. In an example, the first type of dopant is one of a p-type or an n-type dopant, and the second type of dopant is the other of the p-type or the n-type dopant, e.g., depending on a type of a transistor (e.g., PMOS or NMOS) comprising the source and drain regions. In an example, a layer comprises semiconductor material and includes the first type of dopant, where the layer is in contact with, and extends vertically upward from, the sub-fin. In an example, a dielectric material structure is laterally between and separates the layer from the source and drain regions. The layer is a tap or body region of the transistor that contacts the sub-fin. Numerous configurations and variations will be apparent in light of this disclosure.

General Overview

As mentioned herein above, there are various non-trivial issues associated with designing ESD protection devices. For example, a transistor may be coupled to an I/O pad of an integrated circuit chip, where the I/O pad may occasionally experience ESD events. This may expose the transistor (e.g., gate dielectric of the transistor) to the high voltage, which may result in degradation and even failure of the transistor, such as failure of the gate dielectric of the transistor. Accordingly, in an example, diodes may be employed to protect the transistor from such high voltage ESD events. As an example, a diode may be forward biased due to the high ESD voltage, thereby providing a path to the ground plane for the high ESD voltage, so as to protect the transistor from such high voltage. In an example, a diode may be formed adjacent to the transistor, to provide ESD protection to the transistor. However, the diode device architecture may deviate from transistor architecture, thereby preventing close integration of a diode with a transistor. Further, diodes may be designed to be used and routed in large parallel arrays. Individual diodes may be physically larger than individual transistors, and multiple transistors may be connected in parallel to each diode, thereby preventing or reducing fine legging of drivers coupled to I/O pads.

Accordingly, techniques are provided herein to form a transistor integrated with a diode, where the diode can be used for protecting the transistor against ESD events. Integrating the transistor and the diode reduces an area consumption of the diode, e.g., compared to a stand alone diode formed separate from the transistor.

In an example, the transistor is a gate-all-around (GAA) transistor. Examples of GAA channel regions include nanoribbons or other forms of channel regions around which a gate structure wraps. As will be appreciated in light of this disclosure, reference to nanoribbons or GAA as channel regions is also intended to include other gate-all-around or multi-gate channel regions, such as nanowires, nanosheets, and other such semiconductor bodies around which a gate structure can at least partly wrap. To this end, the use of a specific channel region configuration (e.g., nanoribbon) is not intended to limit the present description to that specific channel configuration. Rather, the techniques provided herein can benefit any number of channel configurations, whether those bodies be nanowires, nanoribbons, nanosheets, or some other body around which a gate structure can at least partially wrap, such as the semiconductor bodies of a fin-based device.

In any case, I/O terminals of an integrated circuit chip may experience ESD events, as may transistors that are directly coupled to those I/O terminals. In contrast, transistors such as those used for logic circuits inside the IC chip may not be as susceptible to such ESD events. Transistors that may be less susceptible to ESD events are generally referred to herein as logic transistors that are not directly coupled to I/O terminals. To this end, ESD protection may be used primarily for transistors coupled to the I/O terminals, such as transistors used in receivers, transmitters, or drivers—these transistors are also referred to herein as I/O transistors. Accordingly, the ESD protection diodes can be integrated with such I/O transistors coupled to the I/O terminals, without using such ESD protection diodes for logic transistors within logic circuits of the IC chip, according to some example embodiments.

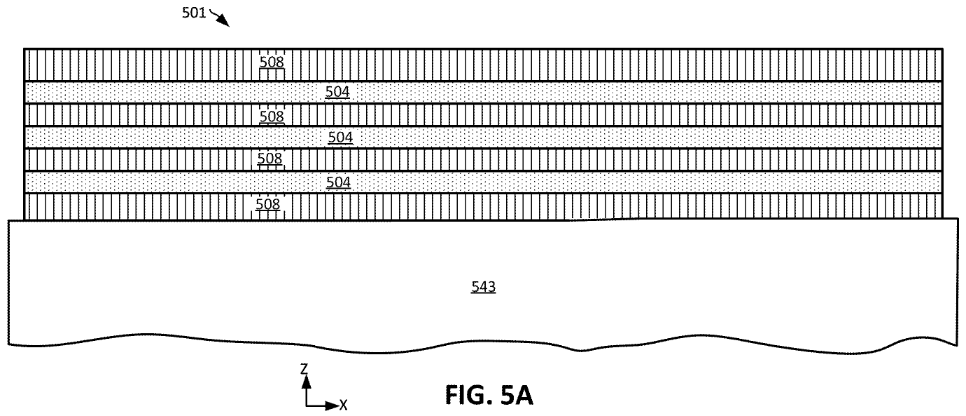

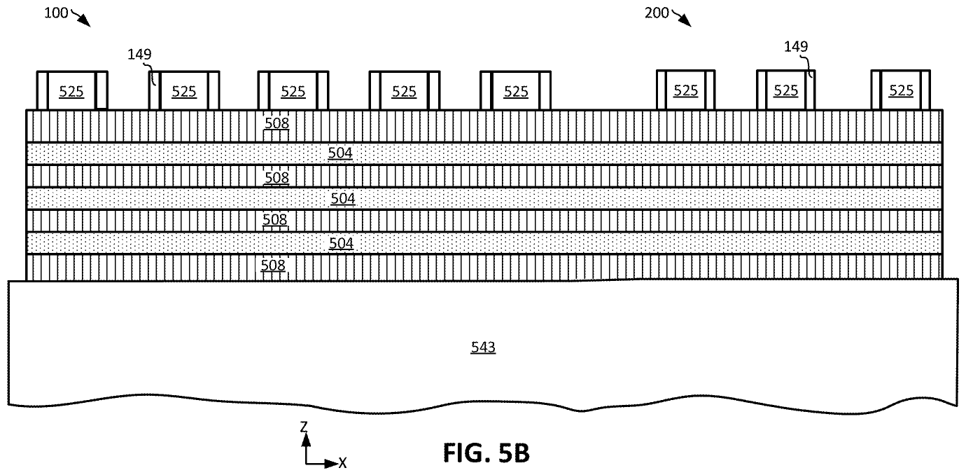

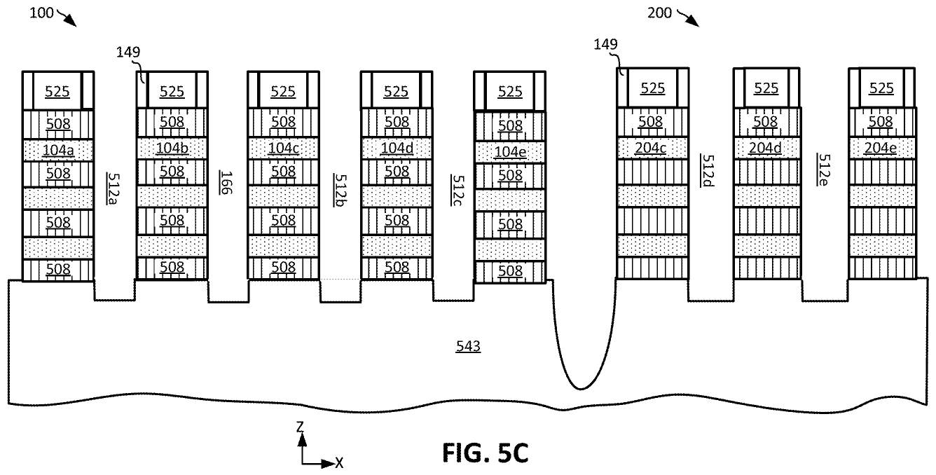

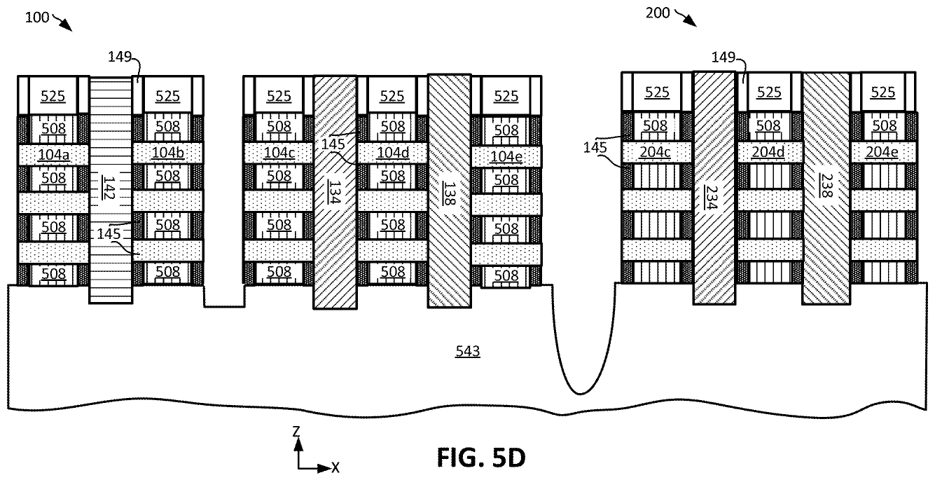

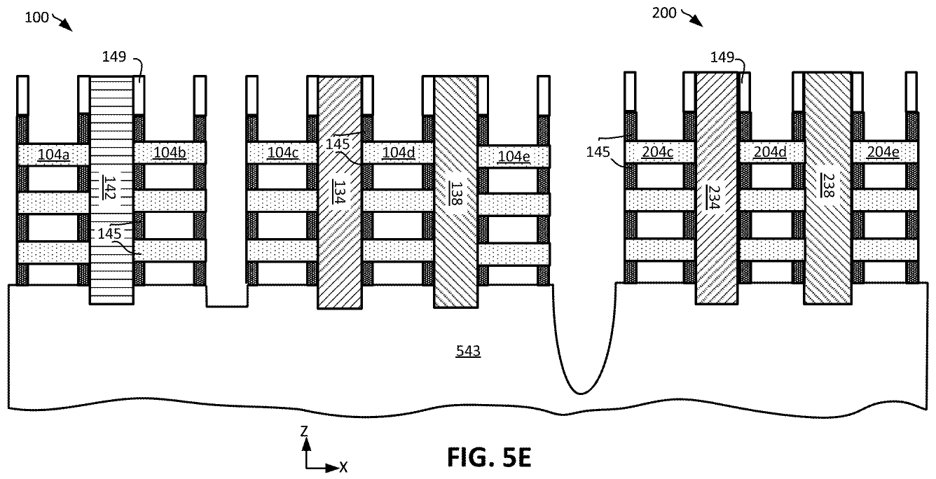

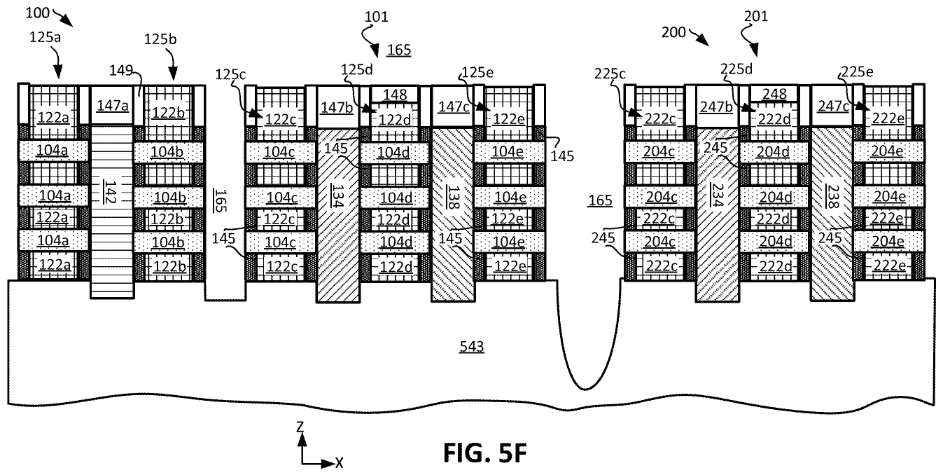

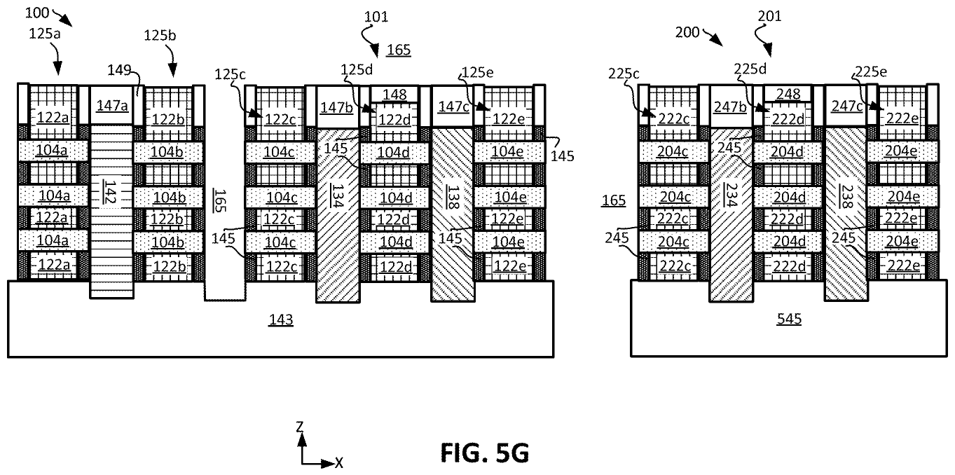

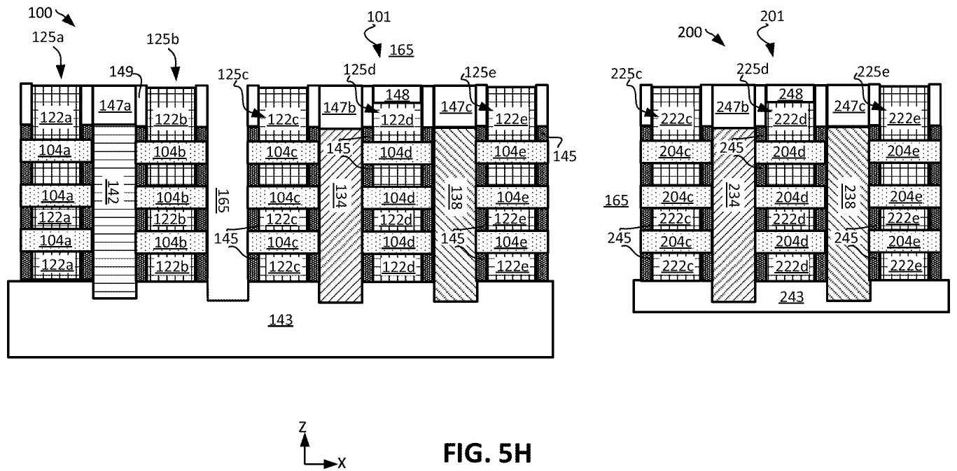

In an example, to integrate a diode with a transistor, a sub-fin area of the transistor is utilized. For example, in a transistor, the nanoribbons (or other GAA channel regions, such as nanoribbons or nanowires, or multi-gate channel regions such as fin-based structure) are above the sub-fin, where the sub-fin comprises semiconductor material. Put differently, the sub-fin is below the nanoribbons, and may not be present in locations that do not have a nanoribbon above it. For example, when forming the nanoribbons, a stack of channel material and sacrificial material is formed above the sub-fin (e.g., see FIG. 5A), and hence, the nanoribbons are formed above the sub-fin. In an example, for transistors used within logic circuits, the sub-fin maybe removed, e.g., from the backside. Merely as an example, the sub-fin may be removed to provide source or drain or gate contacts for the transistors from the backside, and/or may be removed for other reasons (such as formation of conductive vias for backside power and/or signal routing, through areas that originally had the sub-fins). Thus, in an example, logic transistors may not include a sub-fin or a reduced-thickness sub-fin.

However, in an example, the diodes integrated with I/O transistors utilize the sub-fin for current conduction. Thus, when the sub-fins of the logic transistors are being removed (e.g., by a backside etch process), the backside of the I/O transistors may be blocked, e.g., to prevent removal of the sub-fins of the I/O transistors.

In an example, in a I/O transistor, a tap region comprises a doped semiconductor material and contacts the sub-fin, e.g., to couple the sub-fin to an external ground (or power) terminal. The tap region forms a body terminal of the sub-fin. In an example, the tap (or body) region, the source region, and the drain region may have similar shape and formation processes. For ease of identification, the tap region, the source region, and the drain region are generally referred to herein as diffusion regions in plural, and diffusion region in singular. Thus, a diffusion region may refer to any of a tap region contacting the sub-fin, or a source or drain region.

In an example, a transistor structure has a source region, a drain region, and a vertical stack of bodies of semiconductor material extending laterally from the source region to the drain region. The bodies of semiconductor material are the nanoribbons, or other form of channel regions such as nanosheets or nanowires or fin-based structure. A gate structure comprising gate electrode and gate dielectric wraps around individual nanoribbons of the vertical stack. In an example, the source and drain regions contact the sub-fin, and may extend within the sub-fin. For example, for proper operation of the diode, current has to flow between the sub-fin and the source and drain regions. Accordingly, the source and drain regions extending within the sub-fin form a better contact with the sub-fin.

In one embodiment, the I/O transistor structure also includes the tap diffusion region that also extends within the sub-fin (e.g., to form a better contact between the sub-fin and the tap diffusion region). Note that in an example, the above discussed logic transistor may lack such as tap diffusion region.

In one embodiment, nanoribbons also extend from both sides of the tap diffusion region—however, these nanoribbons do not make contact with any source or drain region. Rather, a first end of these nanoribbons is in contact with the tap diffusion region, and a second end of these nanoribbons is in contact with dielectric material (such as interlayer dielectric or ILD).

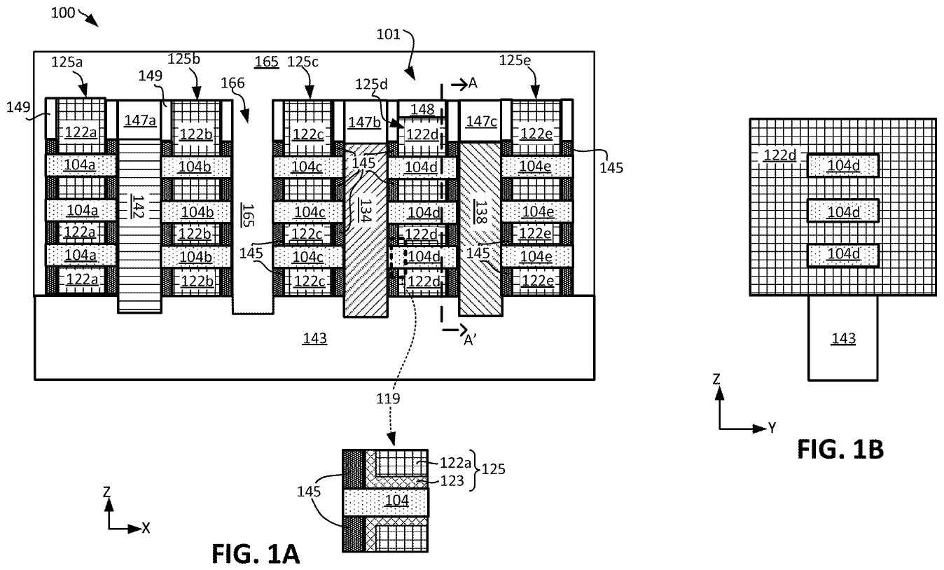

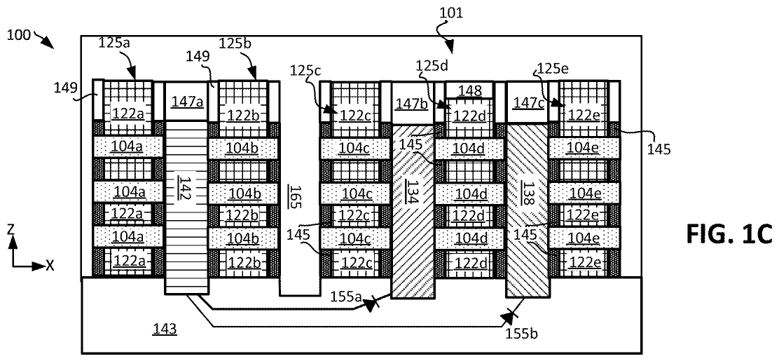

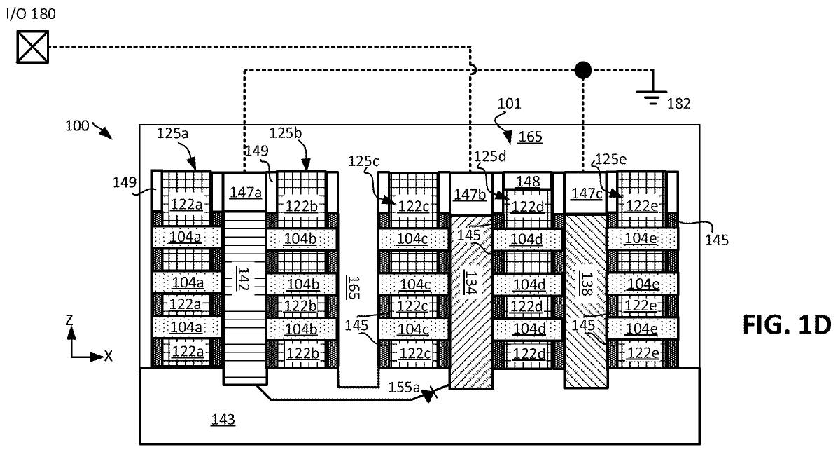

In one embodiment, the ILD is laterally between and separates the tap diffusion region from the source and drain regions. For example, the ILD is at least in part within a trench that extends within the sub-fin (e.g., see trench 166 of FIG. 1A). For example, when forming the structure, initially diffusion region trenches are formed with a regular pitch, where the diffusion region trenches extend within the sub-fin. Later, the tap diffusion region is formed within a first diffusion region trench, the source and drain regions are respectively formed within a second and third diffusion region trenches, and a fourth diffusion region trench is filed with the ILD, to laterally separate the tap diffusion region from the source and drain regions.

In an example, the tap diffusion region and the sub-fin are doped with a first type of dopant, and the source and drain regions are doped with a second type of dopant, where the first type of dopant is one of a p-type or an n-type dopant, and wherein the second type of dopant is the other of the p-type or the n-type dopant. For example, for a NMOS structure, the sub-fin and the tap diffusion region are doped with p-type dopant, and the source and drain region are doped with n-type dopant, examples of which have been discussed herein below. This forms a PN junction between the sub-fin and the source region, and another PN junction between the sub-fin and the drain region. In an example, the source region and the tap region are both electrically coupled to a common terminal. Accordingly, the source region and the tap diffusion region (and also the sub-fin that is in contact with the tap diffusion region and has the same dopant type as the tap diffusion region) are at the same potential, and hence, no functional diode is formed for the PN junction between the sub-fin and the source region.

For a NMOS structure, the n-type drain region is coupled to the I/O terminal, and the n-type source region and the p-type tap region are both coupled to the ground terminal, resulting in the formation of a diode for the PN junction between the sub-fin and the drain region. The p-type tap region and the p-type sub-fin form an anode of the diode, and the n-type drain region forms a cathode of the diode. Note that if the structure is a PMOS instead of an NMOS, the drain region would be coupled to the I/O terminal and may form the anode of the diode. The source region and the tap diffusion region may be coupled to a power supply terminal, and the tap diffusion region may form the cathode. The polarity of the diode would be reversed in this case.

In this configuration, in normal operating mode (e.g., when ESD events do not occur, and the I/O terminal is at a reasonable operating voltage, e.g., within potentials observed on the ground and power nets), the diode is turned off and conducts very little leakage current because of the grounded anode (e.g., the tap diffusion region coupled to ground terminal). In an example, a PMOS diode and an NMOS diode are used for ESD protection. During an ESD event, if the I/O terminal potential falls below the ground potential, the NMOS diode may be forward biased. On the other hand, during the ESD event if the I/O terminal potential goes above the power potential, then the PMOS diode may be forward biased. Thus, either the NMOS diode or the PMOS diode is forward biased and turns on during an ESD event, to safely ground the ESD voltage. If the I/O terminal potential stays within the potential observed on the ground and power nets, then there is no danger to the device and the diodes may not be forward biased and may not turn on. Thus, the diode facilitates in ESD protection of the transistor.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For example, in some embodiments, such tools may be used to detect a transistor structure formed on a sub-fin, and includes a source region and a drain region in contact with the sub-fin, and channel regions (such as nanoribbons, nanowires, or fins) extending from the source region to the drain region. Such tools may also be used to detect a tap diffusion region having the same dopant type as the sub-fin (and different dopant type compared to the source and drain regions), and in contact with the sub-fin. In an example, the source region and the tap diffusion region are both coupled to either a ground terminal or a power terminal (e.g., depending on where the device is a PMOS or an NMOS), and the drain region is coupled to an I/O terminal. Numerous configurations and variations will be apparent in light of this disclosure.

Architecture

FIG. 1A is a cross-sectional view of an integrated diode-transistor circuit structure 100 (also referred to herein as a structure 100) that includes (i) a sub-fin 143 comprising p-type dopant, (ii) a first diffusion region 142 comprising the p-type dopant in contact with the sub-fin 143, (iii) a second diffusion region 134 comprising n-type dopant in contact with the sub-fin 143, (iv) a third diffusion region 138 comprising the n-type dopant in contact with the sub-fin 143, and (v) one or more bodies 104d (e.g., channel regions, such as nanoribbons, nanowires, or nanosheets) of semiconductor material laterally extending from the second diffusion region 134 to the third diffusion region 138, wherein the second and third diffusion regions 134, 138 and the bodies 104d are part of a transistor device 101, and wherein the first diffusion region 142 facilitates formation of parasitic diodes (e.g., diodes 155a, 155b, see FIG. 1C) usable to protect the transistor device 101 against ESD events, in accordance with an embodiment of the present disclosure. FIG. 1B illustrates another cross-sectional view of the structure 100 of FIG. 1A, in accordance with an embodiment of the present disclosure. FIGS. 1C and 1D illustrate the structure 100 of FIG. 1A, and are used to discuss example functionalities of the structure 100 of FIG. 1A, in accordance with an embodiment of the present disclosure.

As can be seen, the cross-sectional view of FIG. 1A is taken parallel to, and through, the channel regions, such that the channel regions 104, and epitaxially formed diffusion regions 134, 138, 142 are shown. The cross-sectional view of FIG. 1B is along line A-A′ of FIG. 1A, and illustrates one stack of channel regions 104 and a gate electrode 122. For example, FIG. 1B illustrates a cross-sectional view of the channel regions 104 comprising nanoribbons, nanowires, or nanosheets, for example.

In the example of FIG. 1A, the diffusion region 134 may be configured to act as a drain region, the diffusion region 138 may be configured to act as a source region, and the diffusion region 142 may be configured to act as a tap or body region for coupling the sub-fin 143 to a ground (or Vcc) terminal. In an example, the source, drain, and the tap diffusion regions (e.g., the diffusion regions 138, 134, 142, respectively) may have similar shape, and may be formed using source and drain formation processes of a transistor. Furthermore, although a single transistor 101 having a single source region 138 and a single drain region 134, along with a single tap diffusion region 142 is illustrated in the example of FIG. 1A, some other examples may include an integrated circuit structure having more of each of these regions (e.g., see FIG. 1D).

The structure 100 includes a plurality of stack of channel regions 104, such as a stack of channel regions 104a, a stack of channel regions 104b, a stack of channel regions 104c, a stack of channel regions 104d, and a stack of channel regions 104e, and a corresponding plurality of gate structures 125a, 125b, 125c, 125d, and 125e, respectively. In an example, individual channel regions 104 are wrapped around by a corresponding gate structure 125. Thus, the structure 100 is a GAA device in which the gate structure 125 wraps around individual channel regions 104.

In an example, individual channel regions 104 are nanoribbons. As will be further appreciated in light of this disclosure, reference to nanoribbons is also intended to include other channel regions, such as nanowires or nanosheets, and other such semiconductor bodies around which a gate structure at least in part wraps around the channel region. To this end, the use of a specific channel region configuration (e.g., GAA) is not intended to limit the present description to that specific channel configuration. In an example, the teachings of this disclosure may also be applicable to devices in which the gate at least partially wrap around the channel region, such as finFET structures having fins as channel regions. Thus, a stack of nanoribbon channel regions 104a may be replaced by a corresponding fin, in one example. Similarly, a stack of nanoribbon channel regions 104a may be replaced by a corresponding stack of nanowires or nanosheets, in another example.

In one embodiment, the structure 100 is formed on a sub-fin 143. In the example of FIG. 1A, the transistor 101 comprises the diffusion regions 134, 138, the nanoribbons 104d laterally extending from the diffusion region 134 to the diffusion region 138, and the gate structure 125d wrapping around the nanoribbons 104d. In an example, the transistor 101 is an NMOS transistor 101, and accordingly, the sub-fin 143 is doped with a p-type dopant. Example p-type dopants include boron, gallium, indium, and aluminum. However, in another example, the transistor 101 may be a PMOS transistor, and the sub-fin 143 may be doped with an n-type dopant. Example n-type dopants include phosphorous and arsenic. In an example, the sub-fin 143 may have an appropriate doping concentration, such as in the range of 1E11 to 1E24. Note that the sub-fin 143 is below the corresponding nanoribbons 104, and may not be present in locations above which the nanoribbons 104 are not present, as illustrated in the cross-sectional view of FIG. 1B.

As illustrated in FIG. 1A, in an example, the structure 100 comprises a plurality of stacks of nanoribbons 104, such as stacks of nanoribbons 104a, 104b, 104c, 104d, 104e. In the example of FIG. 1A, each vertical stack of nanoribbons 104 comprises three nanoribbons. The number of nanoribbons 104 in each vertical stack of nanoribbon (i.e., three nanoribbons per stack) is merely an example, and each vertical stack of nanoribbons may comprise a different number of nanoribbons, such as one, two, four, five or higher number of nanoribbons.

As illustrated, the vertical stack of nanoribbons 104a extends from the diffusion region 142 away from the transistor 101, and the vertical stack of nanoribbons 104b extends from the diffusion region 142 towards the transistor 101. Note that while one end of individual nanoribbons of the stacks 104a, 104b is in contact with the diffusion region 142, another end of individual nanoribbons of the stacks 104a, 104b is in contact with dielectric material 165. The dielectric material 165 may be an interlayer dielectric (ILD) in an example, and may be above various components of the structure 100, as illustrated.

As also illustrated, the nanoribbons 104c extend from the diffusion region 134 and away from the diffusion region 138 (e.g., towards the diffusion region 142). The nanoribbons 104e extend from the diffusion region 138 and away from the diffusion regions 134 and 142. Thus, while one end of individual nanoribbons 104c is in contact with the diffusion region 134, another end of individual nanoribbons 104c is in contact with dielectric material 165. Similarly, while one end of individual nanoribbons 104e is in contact with the diffusion region 138, another end of individual nanoribbons 104e is in contact with dielectric material 165.

In one embodiment, the nanoribbons 104d extend from the diffusion region 134 to the diffusion region 138. For example, one end of individual nanoribbons 104d is in contact with the diffusion region 134, another end of individual nanoribbons 104d is in contact with the diffusion region 138.

Note that each of the nanoribbons 104a, 104b, 104c, and 104e has one end in contact with the dielectric material 165. Thus, the nanoribbons 104a, 104b, 104c, and 104e may act as “dummy” channel region, in that the nanoribbons 104a, 104b, 104c, and 104e may not conduct current between a source and a drain region, and may not act as active channel region of the transistor 101. In contrast, the nanoribbons 104d extending from the diffusion region 134 to the diffusion region 138 selectively conducts current (e.g., based on the voltage applied to the gate structure 135d), and hence, form the active channel regions of the transistor 101.

Although the nanoribbons 104a, 104b, 104c, and 104e may not provide much useful functionality to the structure 100, the nanoribbons 104a, 104b, 104c, and 104e are formed as a standard process of forming nanoribbons within a section of a die comprising the structure 100. For example, the nanoribbons 104a and 104b, along with corresponding sacrificial material and dummy gate stack define a diffusion region trench therebetween, where the diffusion region 142 is eventually formed, thereby facilitating formation of the diffusion region 142.

The nanoribbons 104 may comprise any appropriate semiconductor material, such as group IV material (e.g., silicon, germanium, or SiGe) or group III-V materials (e.g., indium gallium arsenide). In other embodiments, the nanoribbons 104 may be replaced by fins on which the corresponding gate structures are formed to provide double-gate or tri-gate configurations (as opposed to gate-all-around configurations with nanoribbons or wires). The nanoribbons 104 may be doped. For example, nanoribbons 104c, 104d, 104e may have the same type of doping as the diffusion regions 134, 138, and nanoribbons 104a, 104b may have the same type of doping as the diffusion region 142. In other examples, the nanoribbons 104 may be partially doped (e.g., such as the example case where a nanoribbon is doped at its ends but not in the middle portion), or undoped, and may be shaped or sculpted during the gate formation process, according to some embodiments. In some cases, the nanoribbons 104 may be a multilayer structure, such as a SiGe body cladded with germanium, or a silicon body cladded with SiGe. Any number of channel configurations can be used.

According to some embodiments, the diffusion regions 134, 138, 142 are epitaxial regions that are provided using an etch-and-replace process. In other embodiments one or more of the diffusion regions could be, for example, implantation-doped native portions of the semiconductor fins or substrate. Any semiconductor materials suitable for source and drain regions can be used (e.g., group IV and group III-V semiconductor materials). The diffusion regions may include multiple layers such as liners and capping layers to improve contact resistance. In any such cases, the composition and doping of the diffusion regions, including the source diffusion region 138, the drain diffusion region 134, and the tap diffusion region 142, may be the same or different, depending on the polarity of the transistors, as will be discussed in further detail herein below. Any semiconductor materials suitable for source and drain regions can be used (e.g., group IV and group III-V semiconductor materials).

Referring again to FIG. 1A, in some embodiments, conductive contacts are formed over various regions of the structure 100. For example, conductive contacts 147a, 147b, 147c are respectively formed on the diffusion regions 142, 134, and 138, respectively; and conductive gate contact 148 is formed over the gate structure 125d. The conductive contacts may be any suitably conductive material, such as one or more metals and/or alloys thereof. In some embodiments, conductive contacts include one or more of the same metal materials as gate electrode, or a different conductive material.

Note that in an example, the gate structures 125a, 125b, 125c, and/or 125e are not contacted. Thus, there are no corresponding gate contacts for these gate structures. In an example, the gate structures 125a, 125b, 125c, and/or 125e are dummy gate structures and are electrically floating, and do not impart any meaningful functionality in the structure 100. In an example, the gate structures 125a, 125b, 125c, and/or 125e are present in the structure, e.g., because gate structures are formed with regular pitch or interval within at least a section of a die that includes the structure, and the gate structures 125a, 125b, 125c, and/or 125e are formed as a part of gate structure formation for multiple devices.

The gate structure 125a contacts and wraps around individual nanoribbons 104a, the gate structure 125b contacts and wraps around individual nanoribbons 104b, the gate structure 125c contacts and wraps around individual nanoribbons 104c, the gate structure 125d contacts and wraps around individual nanoribbons 104d, and the gate structure 125e contacts and wraps around individual nanoribbons 104e. Note that in another example where the structure 100 includes a fin instead of a stack of nanoribbons, the corresponding gate structure is on and partly wraps around (e.g., is on three sides) the fin.

In one embodiment, each gate structure 125 includes a gate dielectric 123 that wraps around middle portions of each nanoribbon, and a gate electrode 122 that wraps around the gate dielectric. The gate dielectric 123 is illustrated in an expanded view of a section 119 of the structure 100. As illustrated, the gate electrode 122a of the gate structure 125a wraps around middle portions of individual nanoribbons 104a, the gate electrode 122b of the gate structure 125b wraps around middle portions of individual nanoribbons 104b, the gate electrode 122c of the gate structure 125c wraps around middle portions of individual nanoribbons 104c, and so on. Note that the middle portion of each nanoribbon 104 is between a corresponding first end portion and a second end portion, where the first end portions of the nanoribbons of a stack is wrapped around by corresponding first inner gate spacer 145, and where the second end portions of the nanoribbons of a stack is wrapped around by corresponding second inner gate spacer 145.

In some embodiments, the gate dielectric 123 may include a single material layer or multiple stacked material layers. The gate dielectric 123 may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 123 is lanthanum. In some embodiments, the gate dielectric can be annealed to improve its quality when high-k dielectric material is used. In some embodiments, the gate dielectric 123 includes a first layer (e.g., native oxide of nanoribbons, such as silicon dioxide or germanium oxide or SiGe-oxide) on the nanoribbons, and a second layer of high-k dielectric (e.g., hafnium oxide) on the first layer. The gate dielectric 123 is present around middle portions of each nanoribbon, and although not illustrated, may also be present over sub-fin 143, and/or on inner sidewalls of the inner gate spacers 145.

In one embodiment, one or more work function materials (not illustrated in FIG. 1A) may be included around the nanoribbons 104. Note that work function materials are called out separately, but may be considered to be part of the gate electrodes. In this manner, a gate electrode 122 may include multiple layers or components, including one or more work function materials, gate fill material, capping or resistance-reducing material, to name a few examples. In some embodiments, a p-channel device may include a work function metal having titanium, and an n-channel device may include a work function metal having tungsten or aluminum, although other material and combination may also be possible. In some other embodiments, the work function metal may be absent around one or more nanoribbons. In still other embodiments, there may be insufficient room for any gate fill material, after deposition of work function material (i.e., a given gate electrode may be all work function material and no fill material). In an example, the gate electrodes 122 may include any sufficiently conductive material, such as a metal, metal alloy, or doped polysilicon. The gate electrodes may include a wide range of materials, such as polysilicon or various suitable metals or metal alloys, such as aluminum, tungsten, titanium, tantalum, copper, cobalt, molybdenum, titanium nitride, or tantalum nitride, for example. Numerous gate structure configurations can be used along with the techniques provided herein, and the present disclosure is not intended to be limited to any particular such configurations.

Each gate structure 125 also includes two corresponding inner gate spacers 145 that extend along the sides of the gate electrode 122, to isolate the gate electrode 122 from an adjacent diffusion region (or from the dielectric material, e.g., for the right end of nanoribbons 104b or 104e). The inner gate spacers 145 at least partially surround the end portions of individual nanoribbons. In one embodiment, gate spacers 134 may include a dielectric material, such as silicon nitride, for example.

As discussed herein above, the gate structures 125a, 125b, 125c, and/or 125e are dummy gates, e.g., are electrically floating, whereas the gate structure 125d is coupled to an external circuit through the gate contact 148. In an example, the dummy gate structures (e.g., gate structure 124c) do not impart any meaningful control over the corresponding dummy nanoribbons (e.g., nanoribbon 104c). For example, one end of the dummy nanoribbons 104c are in contact with the drain diffusion region 134, while the other end of the nanoribbons 104c are not coupled to any source or drain region. Accordingly, the nanoribbons 104c do not conduct any current and are dummy nanoribbons, for example, as also discussed herein above.

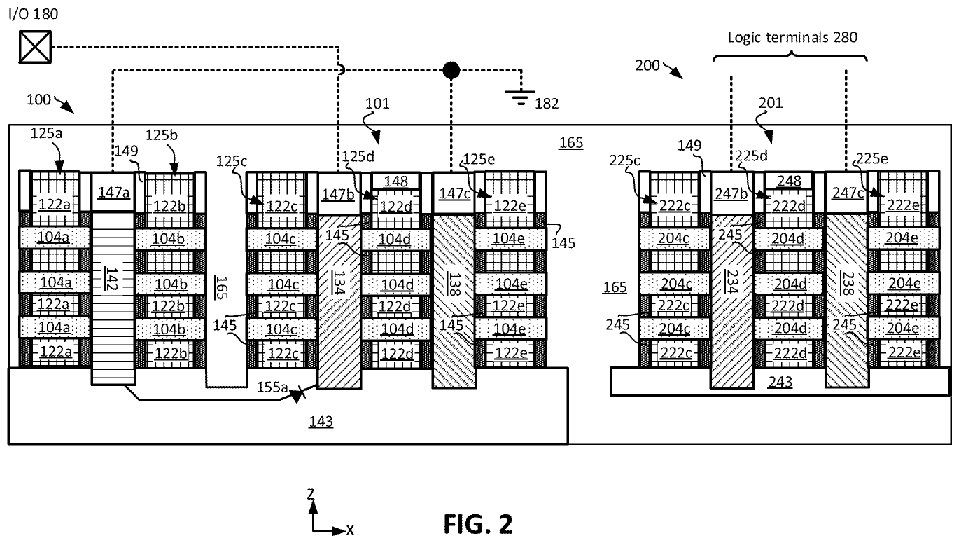

As illustrated, each diffusion region 142, 134, and 138 in part extend within the sub-fin 143. Extension of the diffusion regions within the sub-fin results in a better contact between the sub-fin and the diffusion regions. Although the source diffusion region 138 and the drain diffusion region 134 need not contact the sub-fin 143 during regular operation of the transistor 101, such better contact between a diffusion region and the sub-fin 143 may come into play during operation of the diode 155a (see FIGS. 1D and 2), e.g., during an ESD event.

In an example, a trench 166 comprising the dielectric material (e.g., ILD) 165 is laterally between the diffusion regions 142 and 134 (e.g., laterally between the nanoribbons 104b and 104c). In an example, the trench 166 comprising dielectric material 165 may also in part extend within the sub-fin 143. For example, trenches for formation of the various diffusion regions 142, 134, 138 and the trench 166 are formed using one or more same diffusion trench etching process, and hence, the trench 166 may also extend within the sub-fin 143.

As discussed herein above, in the example of FIG. 1A, the transistor 101 is an NMOS transistor, in which the source and drain regions 138, 134, respectively, are doped with n-type dopant, the tap region 142 is doped with p-type dopant, and the sub-fin 143 is doped with p-type dopant. Note that in another example, the transistor 101 can be a PMOS, in which the case the type of dopants of the diffusion regions and the sub-fin 143 would be reversed.

Thus, the diffusion region 142 and the sub-fin 143 are doped with the same type of dopant. For example, both the diffusion region 142 and the sub-fin 143 are doped with p-type dopant, if the transistor 101 is an NMOS; and both the diffusion region 142 and the sub-fin 143 are doped with n-type dopant, if the transistor 101 is a PMOS. In contrast, the diffusion regions 138, 134 (e.g., source and drain regions) are doped with dopant type that is opposite of the dopant type of the diffusion region 142 and the sub-fin 143. Accordingly, a diode 155a may be formed based on the PN junction between the sub-fin 143 and the diffusion region 134, and another diode 155b may be formed based on the PN junction between the sub-fin 143 and the diffusion region 138, as illustrated in FIG. 1C.

For example, assuming the transistor 101 is an NMOS, for the diode 155a, the diffusion region 142 and the sub-fin 143 form the anode, the diffusion region 134 forms the cathode, a contact 147a of the diffusion region 142 forms a terminal of the anode, and a contact 147b of the diffusion region 134 forms a terminal of the cathode. Note that if the transistor 101 is a PMOS, the anode and cathodes would be reversed.

Similarly, assuming the transistor 101 is an NMOS, for the diode 155b, the diffusion region 142 and the sub-fin 143 form the anode, the diffusion region 138 forms the cathode, the contact 147a of the diffusion region 142 forms a terminal of the anode, and a contact 147c of the diffusion region 138 forms a terminal of the cathode. Note that if the transistor 101 is a PMOS, the anode and cathodes would be reversed.

FIG. 1D symbolically illustrates (e.g., using dotted lines) example connections of various contacts of the structure 100 of FIG. 1A. The connections of FIG. 1D assumes that the transistor 101 is an NMOS. For example, in FIG. 1D, the drain diffusion region 134 is coupled to an I/O terminal 180 of the IC chip, through which the IC chip may interface with devices external to the IC chip on which the structure 100 is implemented. The I/O terminal 180 may be any conventional I/O pad, pin, post, wire, etc. In an example, the transistor 101 may be part of a transmitter, a receiver, or a driver circuit coupled to the I/O terminal 180. In an example, ESD events (e.g., high ESD voltage and/or current) may occur in the I/O terminal 180.

The diffusion region 142 (e.g., the tap region) and the source diffusion region 138 are coupled to a ground terminal 182. Note that in the example of FIG. 1D, because the diffusion regions 138 and 142 are both coupled to the ground and maintained at the same potential, the diode 155b (see FIG. 1C) may not be functional, and hence, not illustrated in FIG. 1D.

In an example, individual connections may be implemented with corresponding one or more interconnect features, such as conductive vias and/or conductive lines, which are symbolically depicted using dotted lines in FIG. 1D. For example, one or more metallization levels of the integrated circuit chip may be used for the interconnections.

In an example, the diode 155a may be parasitic in nature, and is formed using the sub-fin 143. The diode 143 is formed by adding the tap diffusion region 142 contacting the sub-fin 143. In this configuration, in normal operating mode (e.g., when ESD events do not occur, and the I/O terminal is at a reasonable operating voltage, e.g., within potentials observed on the ground and power nets), the diodes are turned off and conduct very little leakage current because of the grounded anode (e.g., the tap diffusion region coupled to ground terminal). In an example, a PMOS diode and an NMOS diode are used for ESD protection. During an ESD event, if the I/O terminal potential falls below the ground potential, the NMOS diode may be forward biased. On the other hand, during the ESD event if the I/O terminal potential goes above the power potential, then the PMOS diode may be forward biased. Thus, either the NMOS diode or the PMOS diode is forward biased and turns on during an ESD event, to safely ground the ESD voltage. If the I/O terminal potential stays within the potential observed on the ground and power nets, then there is no danger to the device and the diodes may not be forward biased and may not turn on. Thus, the diodes facilitate in ESD protection of the transistor.

Note that if the transistor 101 is a PMOS instead of an NMOS, the drain diffusion region 134 would be coupled to the I/O terminal and may form the anode. The source diffusion region and the tap diffusion region 142 may be coupled to a power supply terminal, and the tap diffusion region 142 may form the cathode. The polarity of the diode 155a would be reversed in this case.

FIG. 2 illustrates the integrated diode-transistor circuit structure 100 of FIGS. 1A-1D laterally adjacent to a transistor structure 200, in accordance with an embodiment of the present disclosure. For example, the structures 100 and 200 may be within a same area or section of the integrated circuit chip, and laterally separated from each other by at most 100 nm, or at most 200 nm, or at most 400 nm, or at most 1000 nm, or at most 1200 nm, for example.

The structure 200 comprises diffusion regions 234 and 238, one of which may be a source region and the other of which is a drain region of a transistor 201 of the structure 200. Gate stacks 225c, 225d, 225e are adjacent to the diffusion regions 234, 238, where each gate stack 225 comprises corresponding gate electrode 222 and gate dielectric (not illustrated). Also illustrated are the nanoribbons 204c, 204d, 204e. The transistor structure 200 will be apparent, based on the discussion with respect to the transistor 101 of the structure 100 of FIGS. 1A-1D.

Note that the structure 100 is formed on a sub-fin 143. The structure 200 is formed on a component 243, where the component 234 may be a sub-fin, a substrate, or dielectric material. Furthermore, the tap diffusion region 142 of the structure 100 is in contact with the sub-fin 143, resulting in the formation of the parasitic diode 155a based on the PN junction between the sub-fin 143 and the diffusion region 134. In contrast, there is no such tap diffusion region in the structure 200. Accordingly, unlike the diode 155a within the structure 100, no parasitic diode may be formed for the structure 200.

In an example, the diffusion regions 234, 238 of the structure 200 (e.g., which may be the source and drain regions of the transistor structure 200) are coupled to terminals 280 of a logic circuit. Thus, while the diffusion region 134 of the structure 100 is coupled to the I/O terminal 180, the diffusion regions 234, 238 of the structure 200 are coupled to the logic terminals 280. Also, ESD events generally occurs at the I/O terminal, and ESD events do not generally occur at the logic terminals 280. This is because the logic terminals 280 are internal to the IC chip, whereas the I/O terminal 180 is coupled to outside circuits, thereby increasing chances of ESD events at the I/O terminal 180. In an example, the diode 155a protects the structure 100 from such ESD events. However, as ESD events do not occur at the logic terminals 280, the structure 200 may not need a diode integrated with the transistor structure 200.

In an example, the structures 100 and 200 may be formed using at least one or more common processes. For example, the nanoribbons of the two structures may be formed using one or more common processes. In an example, a lower surface of the gate structures 125 and 225 of the structures 100 and 200, respectively, may be substantially coplanar (e.g., a vertical separation of at most 1 nm or 2 nm). Similarly, in an example, a lower surface of the lowest nanoribbon 104 of each stack of the structure 100 may be coplanar with a lower surface of the lowest nanoribbon 204 of each stack of the structure 200 (e.g., a vertical separation of at most 1 nm or 2 nm).

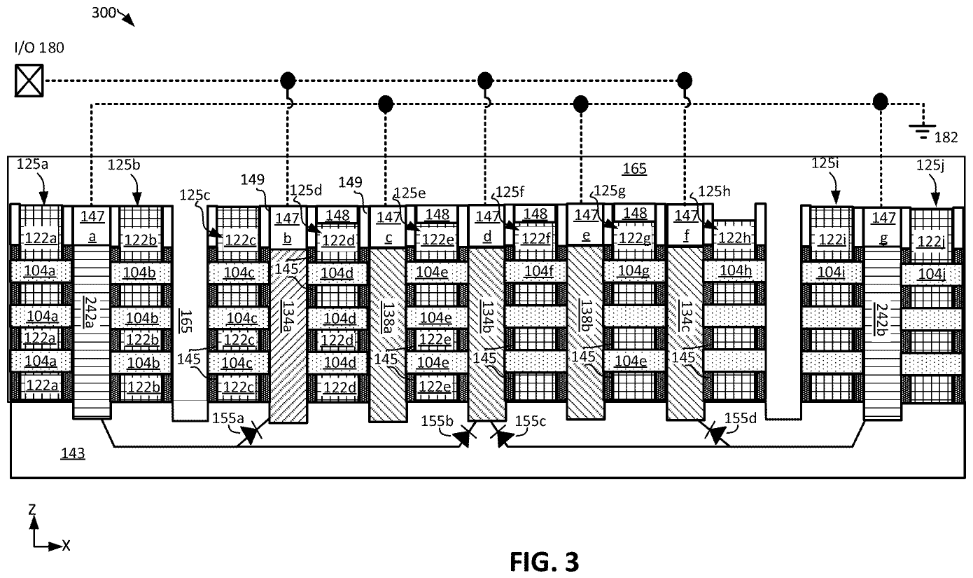

FIG. 3 is a cross-sectional view of another integrated diode-transistor circuit structure 300 (also referred to herein as a structure 300), in accordance with an embodiment of the present disclosure. The structure 300 is at least in part similar to the structure 100 of FIGS. 1A-1D, and similar components of the two structures are labelled the same. However, unlike the structure 100 that had a single tap diffusion region 142, the structure 300 includes two tap diffusion regions 242a, 242b (e.g., acts as a tap or contact to the sub-fin 143). In an example, the tap diffusion regions 242a, 242b and the sub-fin 143 are doped using the same type of dopant (e.g., p-type dopant, if the transistors are NMOS).

Also, the structure 300 has multiple source or drain diffusion regions 134a, 138a, 134b, 138b, 134c, although the number of such source or drain diffusion regions may vary from one example to the other. For example, diffusion regions 134a, 134b, 134c may be drain regions, and diffusion regions 138a, 138b may be source regions of multiple transistors. Various gate structures 125 and nanoribbon 104 are illustrated in FIG. 3, which would be apparent based on corresponding discussion with respect to FIGS. 1A-1D.

Also illustrated in FIG. 3 are the various connections, which would be apparent form the discussion with respect to FIG. 1D. For example, the n-type drain diffusion regions 134a, 134b, 134c (e.g., which form the cathodes of various diodes) are coupled to the I/O terminal 180; and the p-type tap diffusion regions 242a, 242b (e.g., which form the anodes of various diodes) and the p-type source diffusion regions 138a, 138b coupled to the ground or Vss terminal 182.

In the example structure 300, a first diode 155a is formed at a PN junction of the sub-fin 143 and the drain diffusion region 134a, where the tap diffusion region 242a and the sub-fin 143 form the anode and the drain diffusion region 134a forms the cathode of the diode 155a. A second diode 155b is formed at a PN junction of the sub-fin 143 and the drain diffusion region 134b, where the tap diffusion region 242a and the sub-fin 143 form the anode and the drain diffusion region 134b forms the cathode of the diode 155b. A third diode 155c is formed at a PN junction of the sub-fin 143 and the drain diffusion region 134b, where the tap diffusion region 242b and the sub-fin 143 form the anode and the drain diffusion region 134b forms the cathode of the diode 155c. A fourth diode 155d is formed at a PN junction of the sub-fin 143 and the drain diffusion region 134c, where the tap diffusion region 242b and the sub-fin 143 form the anode and the drain diffusion region 134c forms the cathode of the diode 155d. The diodes 155a, 155b, 155c, 155d work to protect the transistors of the structure 300 against one or more ESD events, as discussed with respect to FIG. 1D.

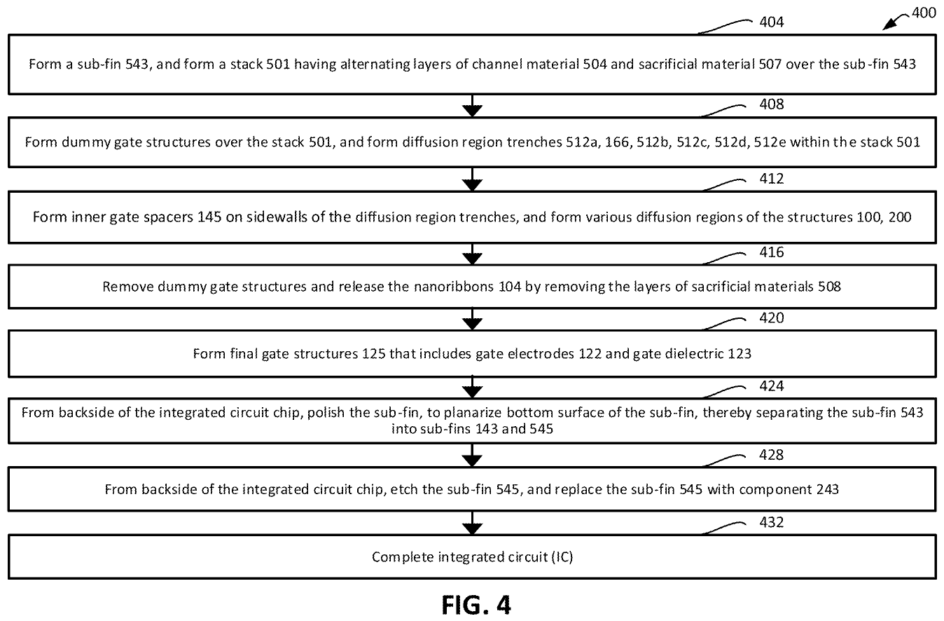

FIG. 4 illustrates a flowchart depicting a method 400 of forming the integrated diode-transistor circuit structure 100 of FIGS. 1A-2 laterally adjacent to the transistor structure 200 of FIG. 2, in accordance with an embodiment of the present disclosure. FIGS. 5A, 5B, 5C, 5D, 5E, 5F, 5G, and 511 collectively illustrate cross-sectional views of the integrated diode-transistor circuit structure 100 of FIGS. 1A-2 and the laterally adjacent transistor structure 200 of FIG. 2 in various stages of processing, in accordance with an embodiment of the present disclosure. FIGS. 4 and 5A-5C will be discussed in unison.

Referring to FIG. 4, the method 400 includes, at 404, from frontside of the integrated circuit chip, forming a sub-fin 543, and forming a stack 501 having alternating layers of channel material 504 and sacrificial material 508 over the sub-fin 543, as illustrated in FIG. 5A. The various layers may be formed using an appropriate deposition process, such as chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example. In an example, the sacrificial material 508 may comprise a semiconductor material, such as SiGe, that is etch selective with respect to the channel material 504 (e.g., Si, or other appropriate semiconductor material, discussed above). For example, an etch process to remove the sacrificial material 508 may not substantially etch the channel material 504.

Referring again to FIG. 4, the method 400 then proceeds from 404 to 408, which includes forming dummy gate structures over the stack 501 (e.g., see FIG. 5B), and forming diffusion region trenches 512a, 166, 512b, 512c, 512d, 512e within the stack 501 (e.g., see FIG. 5C). In an example, each dummy gate structure comprises dummy gate oxide (not labelled in FIG. 5B), dummy gate electrode 525 (e.g., comprising polysilicon, for example), and gate spaces 149. In one embodiment, forming the dummy gate structure may include deposition of a dummy gate oxide, and deposition of a dummy gate electrode 525 (e.g., poly-Si). Gate spacers 149 are formed along opposite sides of the dummy gate electrode 525. For example, the gate spacers 149 comprise silicon nitride (Si₃N₄) and/or other suitable dielectric material, as will be appreciated. The dummy gates are formed in positions where the final metal gates are to be eventually formed for the structures 100 and 200.

Formation of the diffusion region trenches may be performed using an appropriate etch process. Note that the diffusion regions will make electrical contact with the sub-fin. Accordingly, in an example, the diffusion region trenches extend at least in part within the sub-fin, e.g., such that the later formed diffusion regions will have a better electrical contact with the sub-fin. Note that as illustrated, the diffusion region trench formation may also make an undercut in a portion of the sub-fin 543 that is between the structures 100 and 200. For example, a rightmost dummy gate of the structure 100 and a leftmost dummy gate of the structure 200 are spaced sufficiently apart to cause the undercut, as illustrated in FIG. 5C. Also, the various diffusion region trenches divide the stack of channel material 504 into multiple stacks comprising nanoribbons 104a, 104b, . . . , 104e, 204c, 204d, 204e of the structures 100 and 200, interleaved with the sacrificial material 508.

Referring again to FIG. 4, the method 400 then proceeds from 408 to 412, where inner gate spacers 145 are formed on sidewalls of the diffusion region trenches, and then various diffusion regions of the structures 100, 200 are formed, as illustrated in FIG. 5D. The inner gate spacers 145 may be formed using processes used to form such inner gate spacers in GAA transistors. For example, end portions of the sacrificial materials 508 of FIG. 5C are etched (e.g., using a wet etch that uses nitric acid/hydrofluoric acid, an anisotropic dry etch, or other suitable etch process) through the trenches 512a, 166, 512b, 512c, 512d, 512e, to form corresponding recesses, and the inner gate spacers 145 are deposited using an appropriate deposition technique (e.g., CVD, PVD, ALD, VPE, MBE, or LPE, for example) within the thus formed recesses. The deposited inner gate spacers 145 may be planarized, such that tips of the channel materials 104 are exposed through the diffusion region trenches.

Subsequently, diffusion regions 142, 134, 138, 234, and 238 are formed within the trenches 512a, 512b, 512c, 512d, 512e, respectively, e.g., as illustrated in FIG. 5D. In an example, the diffusion regions are formed epitaxially within the corresponding trenches. In some embodiments, the diffusion regions may include any suitable doping scheme, such as including suitable n-type and/or p-type dopant (e.g., in a concentration in the range of 1E16 to 1E22 atoms per cubic cm), as discussed above. Dopant types of various diffusion regions have been discussed herein above.

In an example, when forming one or more diffusion regions having p-type dopant, trenches for diffusion regions having n-type dopant are being masked off; and similarly, when forming one or more diffusion regions having n-type dopant, trenches for diffusion regions having p-type dopant are being masked off, e.g., such that individual diffusion region may be appropriately doped with either p or n type dopant. For example, diffusion region 142 has opposite type of dopant relative to the diffusion regions 134, 138. Accordingly, in an example, when forming the diffusion regions 134, 138, the trench for the diffusion region 142 is masked off, and vice versa. Note that no diffusion region is grown within the trench 166. For example, this trench 166 may be masked off when forming the various other diffusion regions.

Referring again to FIG. 4, the method 400 then proceeds from 412 to 416, where the dummy gate structures are removed, and the nanoribbons 104 are released by removing the layers of sacrificial materials 508, as illustrated in FIG. 5E. In an example, the dummy gate materials (such as dummy gate dielectric and dummy gate electrodes 525) are removed via an etch process that is selective to the gate spacers 149 and inner gate spacers 145 and other non-gate materials exposed during channel and gate processing. Removing the dummy gate electrode between the gate spacers exposes the channel region of the fin. For example, a polycrystalline silicon dummy gate electrode can be removed using a wet etch process (e.g., nitric acid/hydrofluoric acid), an anisotropic dry etch, or other suitable etch process, as will be appreciated. At this stage of processing, the layer stack of alternating layers of channel material and sacrificial material is exposed in the channel region.

The sacrificial material 508 in the layer stack can then be removed by etch processing, to release the nanoribbons 104, in accordance with some embodiments. Etching the sacrificial material 508 may be performed using any suitable wet or dry etching process such that the etch process selectively removes the sacrificial material and leaves intact the channel material. In one embodiment, the sacrificial material is silicon germanium (SiGe) and the channel material is electronic grade silicon (Si). For example, a gas-phase etch using an oxidizer and hydrofluoric acid (HF) has shown to selectively etch SiGe in SiGe/Si layer stacks. In another embodiment, a gas-phase chlorine trifluoride (ClF3) etch is used to remove the sacrificial SiGe material. The etch chemistry can be selected based on the germanium concentration, nanoribbon dimensions, and other factors, as will be appreciated. After removing the SiGe sacrificial material, the resulting channel region includes silicon nanoribbons extending from corresponding diffusion region, where at least one end of each nanoribbon 104 (e.g., silicon) contacts a corresponding diffusion region.

Referring again to FIG. 4, the method 400 then proceeds from 416 to 420, where the final gate structures 125 including gate electrodes 122 and gate dielectric 123 are formed, as illustrated in FIG. 5F. Note that the gate dielectric 123 is not separately labelled in FIG. 5F, and FIG. 5F shows the gate electrodes 122. However, the expanded view of a portion 119 of FIG. 1A illustrates and labels the gate dielectric 123.

Referring again to the method 400 of FIG. 4, the method 400 proceeds from 420 to 424. At 424, from backside of the integrated circuit chip, the sub-fin 543 is polished, to planarize bottom surface of the sub-fin, thereby separating the sub-fin 543 into sub-fin 143 of the structure 100 and the sub-fin 545 of the structure 200, as illustrated in FIG. 5G. For example, the integrated circuit chip is flipped upside down (although the flipping is not illustrated in FIG. 5G, and the integrated circuit chip is shown in its original orientation), and the backside of the integrated circuit chip is processed from the top. Polishing the sub-fin may reduce the height of the sub-fin, resulting in the separation of the sub-fin.

Referring again to the method 400 of FIG. 4, the method 400 proceeds from 424 to 428. At 428, from backside of the integrated circuit chip, the sub-fin 545 is etched, and replaced with component 243, as illustrated in FIG. 5H. The component 243 may be a replacement substrate, a sub-fin with reduced height, or dielectric material. For example, because there is no need of a sub-fin in the structure 200, the sub-fin 545 may be replaced with component 243. However, as the sub-fin 143 is used to form the previously discussed ESD protection diodes 155, the sub-fin 143 is preserved. For example, during process 428, a backside etch block layer, such as a hard mask on the backside, is used to prevent any substantial etching of the sub-fin 143, when the sub-fin 545 of the structure 200 is being etched and replaced.

The method 400 of FIG. 4 then proceeds from 428 to 432, where a general integrated circuit (IC) is completed, as desired, in accordance with some embodiments. Such additional processing to complete an IC may include back-end or back-end-of-line (BEOL) processing to form one or more metallization layers and/or to interconnect the transistor devices formed, for example. Any other suitable processing may be performed, as will be apparent in light of this disclosure.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

Example System

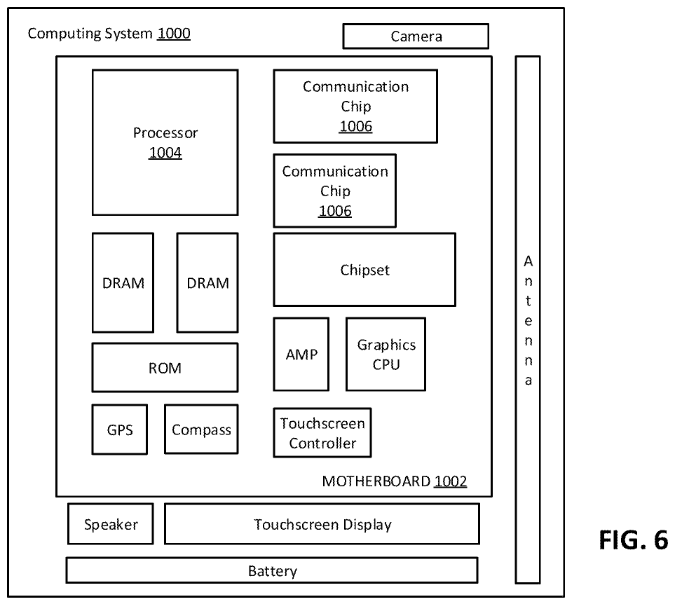

FIG. 6 illustrates a computing system 1000 implemented with integrated circuit structures formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit structure, comprising: a sub-fin having a first type of dopant; a first diffusion region comprising the first type of dopant and in contact with the sub-fin; a second diffusion region and a third diffusion region, each of the second and third diffusion regions comprising a second type of dopant and in contact with the sub-fin, wherein the first type of dopant is one of a p-type or an n-type dopant, and wherein the second type of dopant is the other of the p-type or the n-type dopant, wherein the second diffusion region is laterally between the first and third diffusion regions; a first body of semiconductor material extending from the second diffusion region to the third diffusion region; and a second body of semiconductor material extending from the first diffusion region towards the second diffusion region.

Example 2. The integrated circuit structure of example 1, further comprising: a third body of semiconductor material extending from the first diffusion region and away from the second diffusion region, wherein a first end of the second body is in contact with the first diffusion region and an opposing second end of the second body is not in contact with any diffusion region, and wherein a first end of the third body is in contact with the first diffusion region and an opposing second end of the third body is not in contact with any diffusion region.

Example 3. The integrated circuit structure of example 1, further comprising: a third body of semiconductor material extending from the second diffusion region and towards the first diffusion region, wherein a first end of the third body is in contact with the second diffusion region and an opposing second end of the third body is not in contact with any diffusion region; and a dielectric material structure laterally between, and in contact with, the first body and the third body.

Example 4. The integrated circuit structure of any one of examples 1-3, wherein: each of the first, second, and third diffusion regions at least in part extends within the sub-fin; and the integrated circuit structure further comprises a trench including dielectric material that at least in part extends within the second, the trench including dielectric material laterally between (i) the first diffusion region and (ii) the second and third diffusion regions.

Example 5. The integrated circuit structure of any one of examples 1-4, wherein the third diffusion region is a source region, and the second diffusion region is a drain region.

Example 6. The integrated circuit structure of any one of examples 1-5, wherein the first diffusion region is a tap that connects the sub-fin to a ground terminal or a power terminal.

Example 7. The integrated circuit structure of any one of examples 1-6, further comprising: first one or more interconnect features to electrically couple the second diffusion region to an input/output (I/O) pin of the integrated circuit structure; and second one or more interconnect feature to electrically couple the first and third diffusion regions to a ground terminal.

Example 8. The integrated circuit structure of any one of examples 1-6, further comprising: first one or more interconnect feature to couple the second diffusion region to an input/output (I/O) pin of the integrated circuit structure; and second one or more interconnect feature to couple the first and third diffusion regions to a power terminal.

Example 9. The integrated circuit structure of any one of examples 1-8, further comprising: one or more interconnect feature to electrically couple the first diffusion region to the third diffusion region, wherein the first diffusion region is a tap that contacts the sub-fin, and the third diffusion region is a source region.

Example 10. The integrated circuit structure of any one of examples 1-9, wherein each of the first and second bodies is a nanoribbon, a nanowire, or a nanosheet.

Example 11. The integrated circuit structure of any one of examples 1-10, further comprising: a vertical stack of bodies comprising semiconductor material extending from the second diffusion region to the third diffusion region, the vertical stack of bodies including the first body; and a gate structure wrapping around individual bodies of the vertical stack of bodies.

Example 12. The integrated circuit structure of example 11, where individual bodies of the vertical stack of bodies comprises a nanoribbon, a nanowire, or a nanosheet.

Example 13. The integrated circuit structure of any one of examples 1-12, further comprising: a diode that is based on a PN junction between the sub-fin and the second diffusion region, wherein the first diffusion region and the second form an anode of the diode, and the second diffusion region forms a cathode of the diode.

Example 14. The integrated circuit structure of example 13, wherein the diode is configured to conduct current between the second diffusion region and a ground terminal, during an Electrostatic Discharge (ESD) event occurring in an input/output pin coupled to the second diffusion region.

Example 15. An integrated circuit structure, comprising: a sub-fin having a first type of dopant; a diffusion region having the first type of dopant and in contact with the sub-fin; a source region and a drain region comprising a second type of dopant and in contact with the sub-fin; and a first plurality of interconnect features to electrically couple the diffusion region and the source region to a first terminal, and a second plurality of interconnect features to electrically couple the drain region to a second terminal, wherein one of the first or second terminals is an input/output (I/O) terminal of the integrated circuit structure.

Example 16. The integrated circuit structure of example 15, wherein the first type of dopant is one of a p-type or an n-type dopant, and wherein the second type of dopant is the other of the p-type or the n-type dopant, and wherein the drain region is laterally between the diffusion region and the source region.

Example 17. The integrated circuit structure of example 15, wherein: the first type of dopant is a p-type, and the second type of dopant is an n-type dopant; the first terminal is the I/O terminal of the integrated circuit structure; and the second terminal is a ground terminal.

Example 18. The integrated circuit structure of example 15, wherein: the first type of dopant is an n-type, and the second type of dopant is a p-type dopant; and the first terminal is the I/O terminal of the integrated circuit structure; and the second terminal is a power supply terminal.

Example 19. The integrated circuit structure of any one of examples 15-18, further comprising: a first plurality of bodies extending from the source region to the drain region; a second plurality of bodies extending from the diffusion region towards the drain region; a third plurality of bodies extending from the diffusion region away from the drain region, wherein each of the first, second and third plurality of bodies is above the sub-fin and comprises semiconductor material.

Example 20. The integrated circuit structure of any one of examples 15-19, wherein each of the first, second and third plurality of bodies comprise a vertical stack of nanoribbons, nanowires, or nanosheets.

Example 21. An integrated circuit structure, comprising: a sub-fin having a first type of dopant; a source region and a drain region comprising a second type of dopant, the source and drain regions in contact with and extending vertically upward from the sub-fin, wherein the first type of dopant is one of a p-type or an n-type dopant, and wherein the second type of dopant is the other of the p-type or the n-type dopant; a layer comprising semiconductor material and including the first type of dopant, the layer in contact with, extending vertically upward from, the sub-fin; and a dielectric material structure laterally between and separating the layer from the source and drain regions.

Example 22. The integrated circuit structure of example 21, further comprising a plurality of interconnect features to electrically couple the source region to the layer.

Example 23. The integrated circuit structure of any one of examples 21-22, wherein the plurality of interconnect features electrically couples the source region and the layer to either a ground terminal or a power terminal.

Example 24. The integrated circuit structure of any one of examples 21-23, further comprising: a plurality of interconnect features to electrically couple the drain region to an input/output (I/O) terminal.

Example 25. The integrated circuit structure of any one of examples 21-24, further comprising: a plurality of bodies comprising semiconductor material extending laterally from the layer, wherein each of the plurality of bodies is not in contact with any source or drain region.

Example 26. The integrated circuit structure of any one of examples 21-25, wherein each of the plurality of bodies is a nanoribbon, a nanowire, or a nanosheet.

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit structure, comprising:
a sub-fin having a first type of dopant;
a first diffusion region comprising the first type of dopant and in contact with the sub-fin;
a second diffusion region and a third diffusion region, each of the second and third diffusion regions comprising a second type of dopant and in contact with the sub-fin, wherein the first type of dopant is one of a p-type or an n-type dopant, and wherein the second type of dopant is the other of the p-type or the n-type dopant, wherein the second diffusion region is laterally between the first and third diffusion regions;
a first body of semiconductor material extending from the second diffusion region to the third diffusion region; and
a second body of semiconductor material extending from the first diffusion region towards the second diffusion region.

2. The integrated circuit structure of claim 1, further comprising:
a third body of semiconductor material extending from the first diffusion region and away from the second diffusion region,
wherein a first end of the second body is in contact with the first diffusion region and an opposing second end of the second body is not in contact with any diffusion region, and
wherein a first end of the third body is in contact with the first diffusion region and an opposing second end of the third body is not in contact with any diffusion region.

3. The integrated circuit structure of claim 1, further comprising:
a third body of semiconductor material extending from the second diffusion region and towards the first diffusion region, wherein a first end of the third body is in contact with the second diffusion region and an opposing second end of the third body is not in contact with any diffusion region; and
a dielectric material structure laterally between, and in contact with, the first body and the third body.

4. The integrated circuit structure of claim 1, wherein:
each of the first, second, and third diffusion regions at least in part extends within the sub-fin; and
the integrated circuit structure further comprises a trench including dielectric material that at least in part extends within the second, the trench including dielectric material laterally between (i) the first diffusion region and (ii) the second and third diffusion regions.

5. The integrated circuit structure of claim 1, wherein the third diffusion region is a source region, and the second diffusion region is a drain region.

6. The integrated circuit structure of claim 1, wherein the first diffusion region is a tap that connects the sub-fin to a ground terminal or a power terminal.

7. The integrated circuit structure of claim 1, further comprising:
first one or more interconnect features to electrically couple the second diffusion region to an input/output (I/O) pin of the integrated circuit structure; and
second one or more interconnect feature to electrically couple the first and third diffusion regions to a ground terminal.

8. The integrated circuit structure of claim 1, further comprising:
first one or more interconnect feature to couple the second diffusion region to an input/output (I/O) pin of the integrated circuit structure; and
second one or more interconnect feature to couple the first and third diffusion regions to a power terminal.

9. The integrated circuit structure of claim 1, further comprising:
one or more interconnect feature to electrically couple the first diffusion region to the third diffusion region, wherein the first diffusion region is a tap that contacts the sub-fin, and the third diffusion region is a source region.

10. The integrated circuit structure of claim 1, wherein each of the first and second bodies is a nanoribbon, a nanowire, or a nanosheet.

11. The integrated circuit structure of claim 1, further comprising:
a vertical stack of bodies comprising semiconductor material extending from the second diffusion region to the third diffusion region, the vertical stack of bodies including the first body; and
a gate structure wrapping around individual bodies of the vertical stack of bodies.

12. The integrated circuit structure of claim 1, further comprising:
a diode that is based on a PN junction between the sub-fin and the second diffusion region,
wherein the first diffusion region and the second form an anode of the diode, and the second diffusion region forms a cathode of the diode.

13. The integrated circuit structure of claim 12, wherein the diode is configured to conduct current between the second diffusion region and a ground terminal, during an Electrostatic Discharge (ESD) event occurring in an input/output pin coupled to the second diffusion region.

14. An integrated circuit structure, comprising:
a sub-fin having a first type of dopant;
a diffusion region having the first type of dopant and in contact with the sub-fin;
a source region and a drain region comprising a second type of dopant and in contact with the sub-fin; and
a first plurality of interconnect features to electrically couple the diffusion region and the source region to a first terminal, and a second plurality of interconnect features to electrically couple the drain region to a second terminal, wherein one of the first or second terminals is an input/output (I/O) terminal of the integrated circuit structure.

15. The integrated circuit structure of claim 14, wherein:
the first type of dopant is a p-type, and the second type of dopant is an n-type dopant;
the first terminal is the I/O terminal of the integrated circuit structure; and
the second terminal is a ground terminal.

16. The integrated circuit structure of claim 14, wherein:
the first type of dopant is an n-type, and the second type of dopant is a p-type dopant; and
the first terminal is the I/O terminal of the integrated circuit structure; and
the second terminal is a power supply terminal.

17. The integrated circuit structure of claim 14, further comprising:
a first plurality of bodies extending from the source region to the drain region;
a second plurality of bodies extending from the diffusion region towards the drain region;
a third plurality of bodies extending from the diffusion region away from the drain region,
wherein each of the first, second and third plurality of bodies is above the sub-fin and comprises semiconductor material.

18. An integrated circuit structure, comprising:
a sub-fin having a first type of dopant;
a source region and a drain region comprising a second type of dopant, the source and drain regions in contact with and extending vertically upward from the sub-fin, wherein the first type of dopant is one of a p-type or an n-type dopant, and wherein the second type of dopant is the other of the p-type or the n-type dopant;
a layer comprising semiconductor material and including the first type of dopant, the layer in contact with, extending vertically upward from, the sub-fin; and
a dielectric material structure laterally between and separating the layer from the source and drain regions.

19. The integrated circuit structure of claim 18, further comprising a plurality of interconnect features to electrically couple the source region to the layer, wherein the plurality of interconnect features electrically couples the source region and the layer to either a ground terminal or a power terminal, and/or a plurality of interconnect features to electrically couple the drain region to an input/output (I/O) terminal.

20. The integrated circuit structure of claim 18, further comprising:
a plurality of bodies comprising semiconductor material extending laterally from the layer, wherein each of the plurality of bodies is not in contact with any source or drain region, wherein each of the plurality of bodies is a nanoribbon, a nanowire, or a nanosheet.
